(19) United States
(12) Patent Application Publication
(10) Pub. No.: US 2025/0366161 A1
(43) Pub. Date: Nov. 27, 2025

(54) VERTICALLY STACKED COMPLEMENTARY FIELD EFFECT TRANSISTORS AND METHODS OF FABRICATION THEREOF

(71) Applicant: TAIWAN SEMICONDUCTOR MANUFACTURING COMPANY, LTD., Hsinchu (TW)

(72) Inventors: Shu-Wei Wang, Taichung (TW); Jui-Chien Huang, Hsinchu (TW); Szuya Liao, Hsinchu (TW); Kuan-Kan Hu, Hsinchu (TW)

(21) Appl. No.: 19/292,877

(22) Filed: Aug. 6, 2025

Related U.S. Application Data
(63) Continuation of application No. 18/512,371, filed on Nov. 17, 2023.

(51) Int. Cl. H10D 84/03; H10D 30/01; H10D 30/43; H10D 30/67; H10D 62/10; H10D 64/01; H10D 84/01; H10D 84/85; H10D 88/00

(52) U.S. Cl. CPC H10D 84/038; H10D 30/014; H10D 30/43; H10D 30/6735; H10D 62/121; H10D 64/017; H10D 84/0167; H10D 84/856; H10D 88/01

(57) ABSTRACT

Embodiments of the present disclosure provide a semiconductor device structure having vertically stacked complementary field effect transistors (CFETs). The CFETs are formed by bonding two substrates having semiconductor stacks formed thereon. A bonding structure is formed between the semiconductor stacks using wafer bonding technology. Embodiments of the resent disclosure enable the flexibility of choosing different N/P channel properties, provide a simple way to form the N/P channel isolation structure, and reduce potential leakage path and defects in stacked CFETs.

### CROSS-REFERENCE TO RELATED APPLICATIONS

This application is a continuation application of U.S. patent application Ser. No. 18/512,371 filed Nov. 17, 2023. Each of the aforementioned application is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge.

In pursuit of higher device density, higher performance, and lower costs, challenges from both fabrication and design issues have resulted in the development of three-dimensional designs, such as a multi-gate field effect transistor (FET), including a nanosheet FET. In a nanosheet FET, all side surfaces of the channel are surrounded by the gate electrode, which allows for fuller depletion in the channel and results in less short-channel effects and better gate control. As transistor dimensions are continually scaled down, further improvements of the nanosheet FET are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic flow chart of a method for fabricating a semiconductor device according to embodiments of the present disclosure.

FIGS. 2A-2B, 3A-3B, 4A-4E, 5A-5B to 10A-10B, and 11A-11C schematically illustrate a semiconductor device according during various stages of fabrication according to some embodiments of the present disclosure.

FIGS. 12A-12B and 13A-13B schematically illustrate a semiconductor device according to another embodiment of the present disclosure.

FIGS. 14A-14B, and 15-18 schematically illustrate a semiconductor device according to another embodiment of the present disclosure.

### DETAILED DESCRIPTION

following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure provide a semiconductor device structure having vertically stacked complementary field effect transistors (CFETs). Each CFET is formed by vertically stacking a first nanosheet FET (e.g., an n-channel FET) on a second nanosheet FET (e.g., a p-channel FET). The first nanosheet FET is formed from a first channel stack including one or more first semiconductor channel layers separated by sacrificial semiconductor layers. The second nanosheet FET is formed from a second channel stack including one or more second semiconductor channel layers separated by sacrificial semiconductor layers. In some embodiments, the first channel stack and the second channel stack are epitaxially grown from two different substrates. A bonding layer may be deposited over the first and second channel stacks. The two substrates are bonded using a wafer bonding technology. A bonding structure is formed from the bonding layers. The first and second channel stacks are stacked together and isolated by the bonding structure. The bonding structure and the channel stacks form a combinational Complementary FET (cCFET). By applying wafer bonding technology in CFET integration process, the present disclosure provides flexibility in choosing different N/P channel properties, provides a straightforward way to form the N/P channel isolation structure, and reduces potential leakage paths and defects in stacked CFETs.

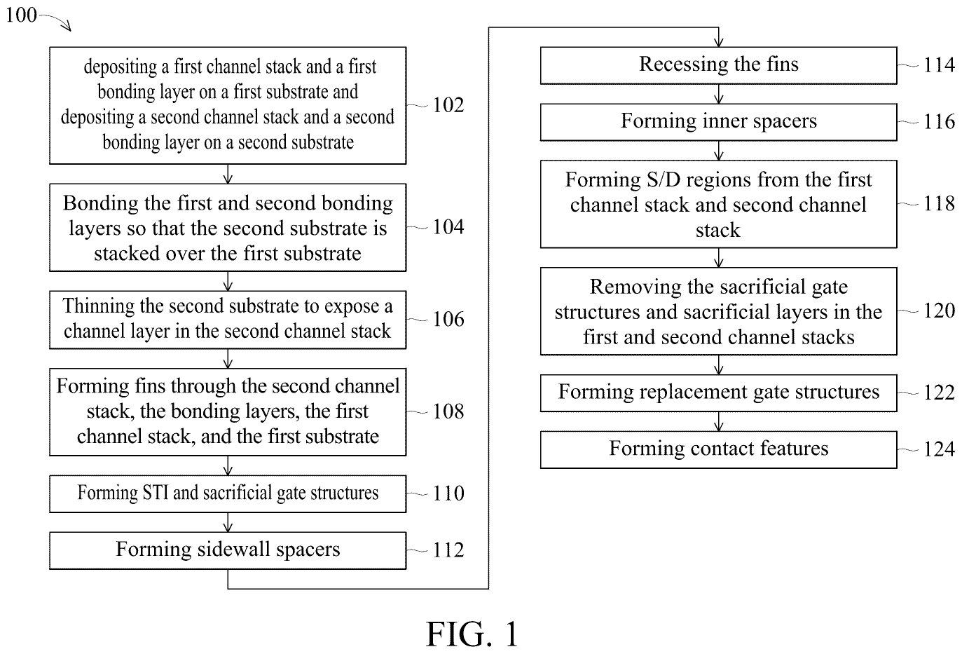

FIG. 1 is a schematic flow chart of a method 100 for fabricating a semiconductor device according to embodiments of the present disclosure. Particularly, the method 100 using substrate bonding technologies to form channel stacks for vertically stacked CFETs.

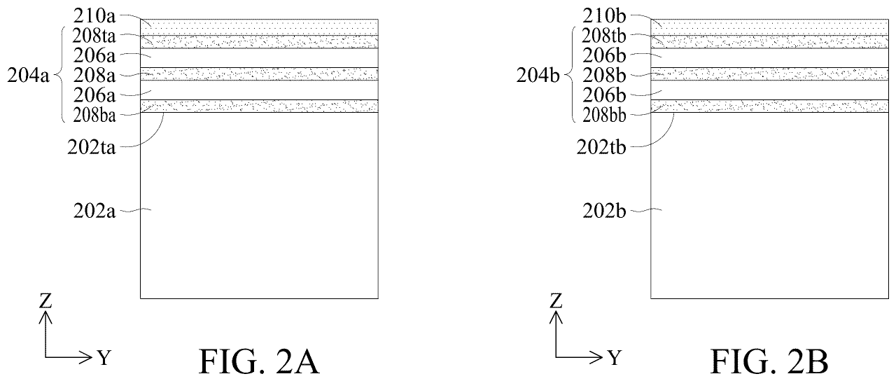

FIGS. 2A-2B, 3A-3B, 4A-4E, 5A-5B to 10A-10B and 11A-11C schematically illustrate a semiconductor device 200 according during various stages of fabrication according to some embodiments of the present disclosure. The semiconductor device 200 may be formed using the method 100. It is understood that additional operations can be provided before, during, and after processes shown by 2A-2B, 3A-3B, 4A-4E, 5A-5B to 10A-10B, and 11A-11C, and some of the operations described below can be replaced or eliminated, for additional embodiments of the present disclosure. The order of the operations/processes is not limiting and may be interchangeable. The semiconductor device 200 includes stacked CFETs having top devices stacked over bottom devices. The top devices and corresponding bottom devices may be complementary field effect transistors with aligned channels.

In operation 102, a first channel stack 204a for bottom devices of the semiconductor device 200 is deposited on a first substrate 202a, as shown in FIG. 2A, and a second channel stack 204b for top devices of the semiconductor device 200 is deposited on a second substrate 202b as shown in FIG. 2B. FIGS. 2A and 2B are cross-sectional views of the first and second substrates 202a, 202b respectfully.

As shown in FIG. 2A, the first channel stack 204a is formed over the first substrate 202a. The first substrate 202a may be a semiconductor substrate configured to have semiconductor devices formed thereon. The first substrate 202a may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiment, the first substrate 202a is made of silicon. In some embodiments, the first substrate 202a is a silicon-on-insulator (SOI) substrate having an insulating layer (not shown) disposed between two silicon layers for enhancement. In one aspect, the insulating layer is an oxygen-containing layer. In some embodiments, the first substrate 202a may include various regions that have been doped with impurities (e.g., dopants having p-type or n-type conductivity). Depending on circuit design, the dopants may be, for example boron for n-type field effect transistors (NFET) and phosphorus for p-type field effect transistor (PFET).

The first channel stack 204a includes semiconductor layers made of different materials to facilitate formation of nanosheet channels in a multi-gate device, such as nanosheet channel FETs. In some embodiments, the channel stack 204a includes first semiconductor layers 206a and second semiconductor layers 208a. The first and second semiconductor layers 206a, 208a are arranged in alternation. The first semiconductor layers 206a and the second semiconductor layers 208a are made of semiconductor materials having different etch selectivity and/or oxidation rates. In some embodiments, the first semiconductor layers 206a may be made of Si and the second semiconductor layers 208a may be made of SiGe. Alternatively, in some embodiments, either of the semiconductor layers 206a, 208a may be or include other materials such as Ge, SiC, GeAs, GaP, InP, InAs, InSb, GaAsP, AllnAs, AlGaAs, InGaAs, GalnP, GalnAsP, or any combinations thereof.

The first semiconductor layers 206a or portions thereof may form nanosheet channel(s) of the semiconductor device 200 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device 200 may be surrounded by a gate electrode. The semiconductor device 200 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 206a to define a channel or channels of the semiconductor device 200 is further discussed below.

The first and second semiconductor layers 206a, 208a are formed by any suitable deposition process, such as epitaxy. By way of example, epitaxial growth of the layers of the channel stack 204a may be performed by a molecular beam epitaxy (MBE) process, a metalorganic chemical vapor deposition (MOCVD) process, and/or other suitable epitaxial growth processes.

As discussed, the semiconductor device 200 to be formed includes a complementary FET (CFET) in which two or more nanosheet FETs are vertically stacked on top of one another. In some embodiments, the first semiconductor layers 206a may define the channels of a first FET, such as n-type FETs (N-FETs). Alternatively, the first semiconductor layers 206a may define the channels of p-type FETs (P-FETs). The thickness of the first semiconductor layers 206a is chosen based on device performance considerations. In some embodiments, each of the first semiconductor layers 206a has a thickness ranging from about 3 nanometers (nm) to about 10 nm. The second semiconductor layers 208a may eventually be removed and serve to define spaces for a gate stack to be formed therein. Each of second semiconductor layers 208a may have a thickness that is equal, less, or greater than the thickness of the first semiconductor layers 206a, depending on device performance considerations. In some embodiments, each of the second semiconductor layers 208a has a thickness that is equal to the thickness of the first semiconductor layers 206a.

As shown in FIG. 2A, the first channel stack 204a starts with a bottommost second semiconductor layer 208ba and ends with a topmost second semiconductor layer 208ta. The bottommost second semiconductor layer 208ba grows from a top surface 202ta of the first substrate 202a.

While two first semiconductor layers 206a and three second semiconductor layers 208a are alternately arranged as illustrated in FIG. 2A, it can be appreciated that any number of first and second semiconductor layers 206a, 208a can be formed in the first channel stack 204a, depending on the predetermined number of nanosheet channels needed for each FET of the semiconductor device 200.

After formation of the first channel stack 204a, a bonding layer 210a is deposited over the topmost second semiconductor layer 208ta of the first channel stack 204a. The bonding layer 210a may include one or more layer of suitable material to bond with the second channel stack 204b deposited on the substrate 202b and provide isolation between the first and second channel stacks 204a, 204b. In some embodiments, the bonding layer 210a includes one or more dielectric layers. For example, the bonding layer 210a may include silicon carbon-nitride (SiCN), silicon oxy-carbon-nitride (SiOCN), silicon oxide, silicon nitride, a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AISiO), zirconium oxide (ZrO), titanium oxide (TiO), tantalum oxide (Ta₂O₅), yttrium oxide (Y₂O₃), silicon oxynitride (SiON), compounds thereof, composites thereof, combinations thereof, or the like. The bonding layer 210a may be formed by a suitable deposition method, such as chemical vapor deposition (CVD), plasma-enhanced CVD (PECVD), spin-on, or the like.

As shown in FIG. 2B, the second channel stack 204b is formed over the second substrate 202b. The second substrate 202b may be a semiconductor substrate. The second substrate 202b may be formed from material similar to the first substrate 202a. In some embodiments, the first substrate 202a may have a first crystalline orientation and the second substrate 202b may have a second crystalline orientation. The first and second crystalline orientations may be different. As discussed below, the crystalline orientations of the first and second substrates 202a, 202b may be selected to achieve optimized mobility in the subsequently formed channels.

The second channel stack 204b includes semiconductor layers made of different materials to facilitate formation of nanosheet channels in a multi-gate device, such as nanosheet channel FETs. In some embodiments, the second channel stack 204b includes third semiconductor layers 206b and fourth semiconductor layers 208b. The third and fourth semiconductor layers 206b, 208b are arranged in alternation. The third semiconductor layers 206b and the fourth semiconductor layers 208b are made of semiconductor materials having different etch selectivity and/or oxidation rates. In some embodiments, the third semiconductor layers 206b may be made of silicon, Ge, SiC, GeAs, GaP, InP, InAs, InSb, GaAsP, AllnAs, AlGaAs, InGaAs, GalnP, GalnAsP and the fourth semiconductor layers 208b may be made of SiGe. In some embodiments, the second semiconductor layers 208a and the fourth semiconductor layers 208b may have similar composition.

The third semiconductor layers 206b or portions thereof may form nanosheet channel(s) of the semiconductor device 200 in later fabrication stages. The use of the third semiconductor layers 206b to define a channel or channels of the semiconductor device 200 is further discussed below.

The third and fourth semiconductor layers 206b, 208b are formed by any suitable deposition process, such as epitaxy. By way of example, epitaxial growth of the layers of the channel stack 204b may be performed by a molecular beam epitaxy (MBE) process, a metalorganic chemical vapor deposition (MOCVD) process, and/or other suitable epitaxial growth processes.

As discussed above, the semiconductor device 200 to be formed includes a complementary FET (CFET) in which two or more nanosheet FETs are vertically stacked on top of one another. In some embodiments, the third semiconductor layers 206b may define the channels of a second FET, such as p-type FETs (P-FETs). Alternatively, the third semiconductor layers 206b may define the channels of n-type FETs (N-FETs). The thickness of the third semiconductor layers 206b is chosen based on device performance considerations. In some embodiments, each of the third semiconductor layers 206b has a thickness ranging from about 3 nanometers (nm) to about 10 nm. The fourth semiconductor layers 208b may eventually be removed and serve to define spaces for a gate stack to be formed therein. Each of fourth semiconductor layers 208b may have a thickness that is equal, less, or greater than the thickness of the third semiconductor layers 206b, depending on device performance considerations. In some embodiments, each of the fourth semiconductor layers 208b has a thickness that is equal to the thickness of the third semiconductor layers 206b.

As shown in FIG. 2B, the second channel stack 204b starts with a bottommost fourth semiconductor layer 208bb and ends with a topmost fourth semiconductor layer 208tb. The bottommost fourth semiconductor layer 208bb grows from a top surface 202tb of the second substrate 202b. As discussed below, unlike the other fourth semiconductor layers 208b, which serve as sacrificial layers to define spacing between the channels, the bottommost fourth semiconductor layer 208bb serves as an etch stop layer during subsequent process, the thickness of the bottommost fourth semiconductor layer 208bb is different from other fourth semiconductor layers 208b. For example, the bottommost fourth semiconductor layer 208bb is thicker than other fourth semiconductor layers 208b. In some embodiments, the bottommost fourth semiconductor layer 208bb has a thickness in a range between about 10 nm and about 20 nm.

While two third semiconductor layers 206b and three fourth semiconductor layers 208b are alternately arranged as illustrated in FIG. 2B, it can be appreciated that any number of third and fourth semiconductor layers 206b, 208b can be formed in the second channel stack 204b, depending on the predetermined number of nanosheet channels needed for each FET of the semiconductor device 200.

After formation of the second channel stack 204b, a bonding layer 210b is deposited over the topmost fourth semiconductor layer 208tb of the second channel stack 204b. The bonding layer 210b is configured to bond with the first substrate 202a via the bonding layer 210a. Similar to the bonding layer 210a, the bonding layer 210b may include one or more layer of suitable material to bond with the first bonding layer 210a and provide isolation between the first and second channel stacks 204a, 204b. In some embodiments, the bonding layer 210b includes one or more dielectric layers. For example, the bonding layer 210b may include silicon carbon-nitride (SiCN), silicon oxy-carbon-nitride (SiOCN), silicon oxide, silicon nitride, a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AISiO), zirconium oxide (ZrO), titanium oxide (TiO), tantalum oxide (Ta₂O₅), yttrium oxide (Y₂O₃), silicon oxynitride (SiON), compounds thereof, composites thereof, combinations thereof, or the like. The bonding layer 210b may be formed by a suitable deposition method, such as chemical vapor deposition (CVD), plasma-enhanced CVD (PECVD), spin-on, or the like.

In some embodiments, the bonding layers 210a, 210b may be symmetrically formed from the same material and substantially the same thickness. In other embodiments, the bonding layers 210a, 210b may be non-symmetrically formed, from different materials and/or different thicknesses, to achieve desired performance or processing efficiency.

As discussed above, the first and second semiconductor layers 206a, 208a are formed by epitaxial growth from the top surface 202ta of the first substrate 202a. Therefore, the semiconductor layers 206a, 208a have the same crystalline orientations as the first substrate 202a. Similarly, the semiconductor layers 206b, 208b have the same crystalline orientations as the second substrate 202b. Because at least portions of the semiconductor layers 206a, 206b are eventually become channels in the subsequently formed FETs, the crystalline orientations of the channel regions may be chosen to have optimized mobility for the corresponding FETs. For example, in silicon, electrons have the greatest mobility in the {100} plane family while holes have the greatest mobility in the {110} plane family. Because N-FETs use electrons as carrier, fabricating N-FETs on a substrate having a (100) top surface may achieve the most mobility. Because P-FETs use holes as carrier, fabricating P-FETs on a substrate having a (110) top surface may achieve the most mobility.

In some embodiments, the first and second substrates 202a, 202b are selected to achieve most mobility for the corresponding FETs to be formed thereon. Particularly, the first substrate 202a and the substrate 202b are selected to have different crystalline orientations so that mobilities of both N-FETs and P-FETs may be tuned or optimized according to circuit design. In some embodiments, the first substrate 202a has a first crystalline orientation and the substrate 202b has a second orientation. The first crystalline orientation is selected to achieve desired mobility in a channel for a first type of devices, such as N-FET or P-FET. The second crystalline orientation is selected to achieve desired mobility in a channel for the second type of devices, such as P-FET or N-FET. In some embodiments, the top surface 202ta of the first substrate 202a is on a (100) plane. The top surface 202tb of the substrate 202b is on a (110) plane.

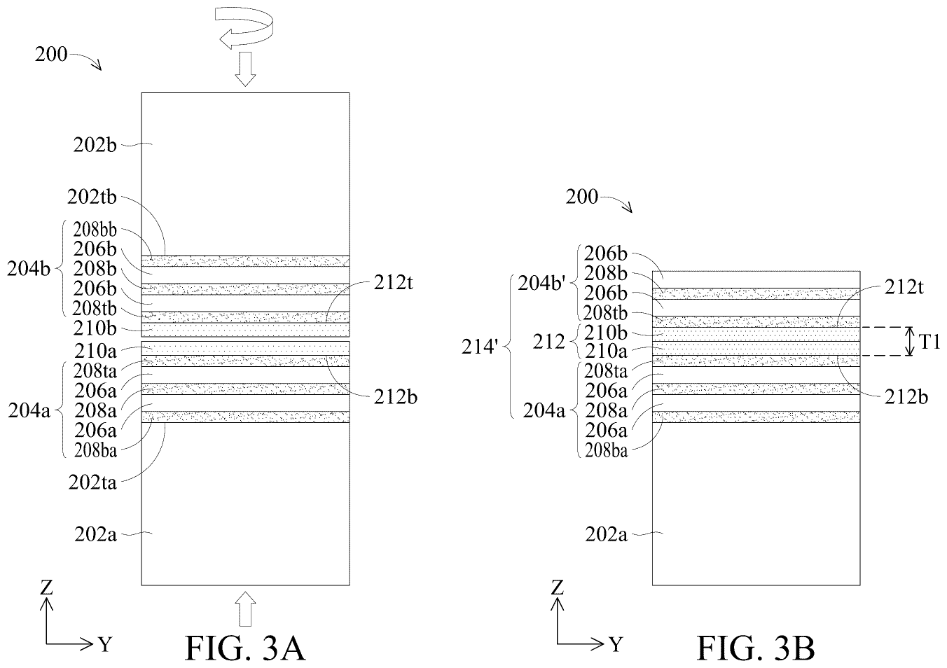

In operation 104, the first substrate 202a and the second substrate 202b are bonded together, as shown in FIG. 3A. FIG. 3A is a schematic cross-sectional view of the semiconductor device 200. The first and second substrates 202a, 202b may be bonded using suitable substrate bonding technology by joining the bonding layers 210a, 210b together.

In some embodiments, the first substrate 202a and the second substrate 202b may be bonded using a direct bonding process, such as dielectric-to-dielectric bonding. In some embodiments, surface cleaning is performed to remove particles, contaminations, and native oxides from surfaces of the first substrate 202a and the second substrate 202b. The surface cleaning process may include one or more cleaning methods, such as cryogenic cleaning, mechanical wiping and scrubbing, etching in a gas, plasma or liquid, ultrasonic and megasonic cleaning, laser cleaning, and the like.

In some embodiments, prior to performing the bonding operation, the first substrate 202a and the second substrate 202b may be positioned relative to each other so that intended channel orientations for in the first channel stack 204a and the second channel stack 204b are aligned with each other.

Subsequently, the bonding layers 210a, 210b of the first and second substrates 202a, 202b are put into physical contact under appropriate bonding pressures and temperatures to form a bonding structure 212 therebetween. The first channel stack 204a, the bonding structure 212, and the second channel stack 204b form a complementary channel stack 214.

In some embodiments, an optional annealing may be performed to enhance the bonding strength in the bonding structure 212 between first and second substrates 202a, 202b. In some embodiments, annealing may be performed at a temperature between about 250° C. and about 400° C. for a time interval between about 0.5 hour and about 4 hours.

The bonding structure 212 has a top surface 212t in contact with the topmost fourth semiconductor layer 208b and a bottom surface 212b in contact with the topmost second semiconductor layer 208a. In some embodiments, the bonding structure 212 may have a thickness T1, from the top surface 212t to the bottom surface 212b, in a range between about 5 nm and about 30 nm. If the bonding structure 212 is thicker than 30 nm, the complementary channel stack 214 may be too high resulting in high aspect ratio in the following etching process. If the bonding structure 212 is thinner than 5 nm, it may be difficult to control the thickness of the bonding structure 212, or the thickness of subsequent dielectric layer between source/drain regions causing source/drain structures of the top and bottom devices to merge.

In operation 106, a thinning process is performed to remove the second substrate 202b, as shown in FIG. 3B. FIG. 3B is a schematic cross-sectional view of the semiconductor device 200. In some embodiments, the thinning process may be performed by a back side grinding process followed by an etch process to selectively remove the second substrate 202b from the complementary channel stack 214. During etching of the second substrate 202b, the bottommost fourth semiconductor layer 208bb serves as an etch stop layer. After removal of the second substrate 202b, a subsequent etch process is performed to remove the bottommost fourth semiconductor layer 208bb so that the third semiconductor layer 206b is exposed, as shown in FIG. 3B.

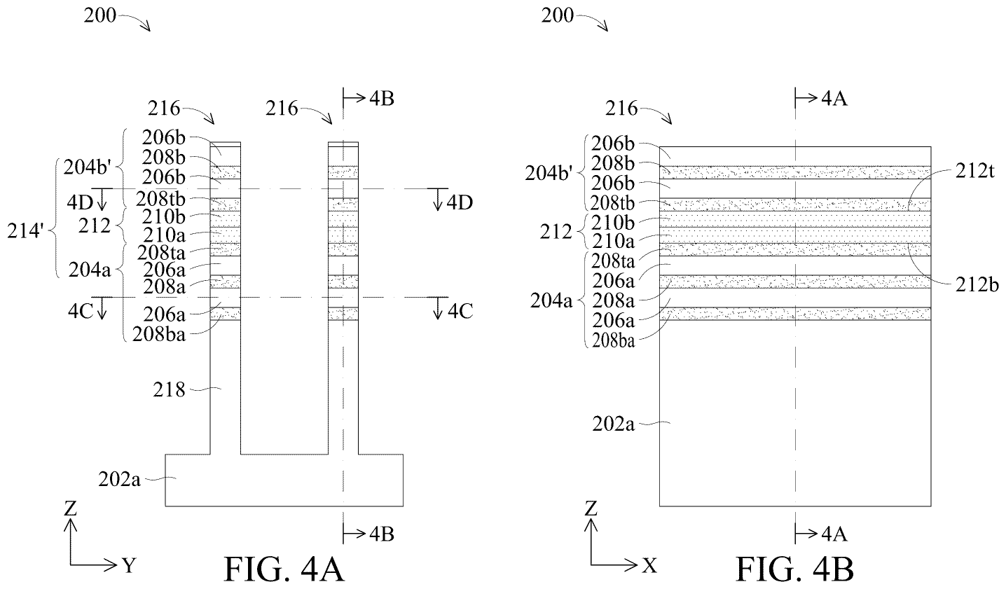

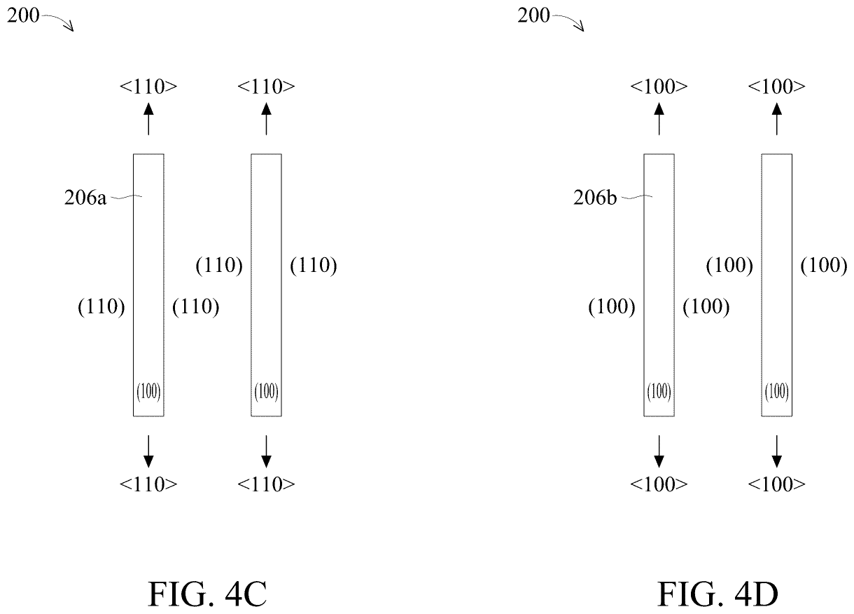

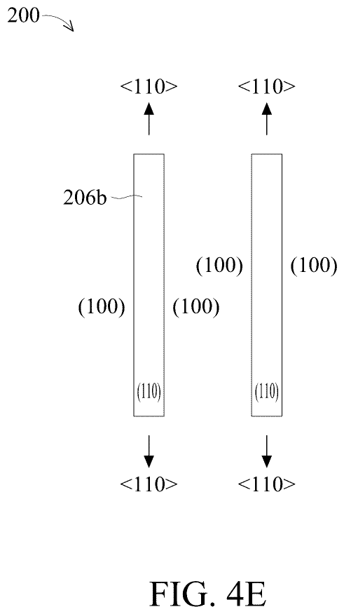

In operation 108, fin structures 216 are formed from the channel stack 204 as shown in FIGS. 4A-4B. FIGS. 4A-4B are sectional views of the semiconductor device 200 after operation 108. FIG. 4A is a schematic sectional view along the line 4A-4A in FIG. 4B. FIG. 4B is a schematic sectional view along the line 4B-4B in FIG. 4A. Each fin structure 216 has an upper portion including the complementary channel stack 214 and a well portion 218 formed from the substrate 202a.

The fin structures 216 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin structures 216 by etching the complementary channel stack 214 and the substrate 202a. The etch process can include dry etch, wet etch, reactive ion etch (RIE), and/or other suitable processes.

The fin structures 216 are formed along the direction of the channel so that portions of the fin structures 216 become channels of the subsequently formed FETs. As discussed above, because the first channel stack 204a and the second channel stack 204b are epitaxially grown from different substrates 202a, 202b, the semiconductor layers in the channel stacks 204a, 204b may have same or different crystalline orientations. Therefore, crystalline orientation in channels of the N-FET and crystalline orientation in the channels of the P-FET may have various combinations by selecting different crystalline orientations of the substrates 202a, 202b. Additionally, alignment between the first channel stack 204a and the second channel stack 204b may be adjusted to have various combination of channel directions.

FIGS. 4C and 4D are schematic cross sectional views along the 4C-4C line and 4D-4D line in FIG. 4A. FIGS. 4C and 4D schematically demonstrate an exemplary crystalline orientations and channel directions of the stacked CFET in the semiconductor device 200. Channels in the bottom FET are formed in the first semiconductor layers 206a along the fin structure 216. Channels in the top FET are formed in the third semiconductor layers 206b along the fin structure 216. In some embodiments, the bottom FET is a N-FET and the top FET is a P-FET. In some embodiments, the channels of the bottom FET (N-FET) are formed from semiconductor layers 206a grown from the (100) plane and sidewalls of the fin structures 216 are cut along the (110) plane so that the channels are along the <110>direction to implement most mobility, as shown in FIG. 4C. In some embodiments, the channels of the top FET (P-FET) are formed from semiconductor layers 206b grown from the (100) plane and sidewalls of the fin structures 216 are cut along the (100) plane so that the channel are formed along the <100> direction, as shown in FIG. 4D. The channel directions shown in FIG. 4D may be selected to achieve N-favorite nanosheets. Alternatively, channel directions may be selected to achieve p-favorite nanosheet. For example, the channels of the P-FET may be formed from semiconductor layers 206 grown from the (110) plane and sidewalls of the fin structures 216 are cut along the (100) plane so that the channels are formed along the <110> direction, as shown in FIG. 4E for a semiconductor device 200a according to another embodiment of the present disclosure.

Alternatively, the top FET may be a N-FET and the bottom FET may be a P-FET, and the channel directions may be selected differently. In some embodiments, the channel directions may be selected in other combinations to achieve different design purposes.

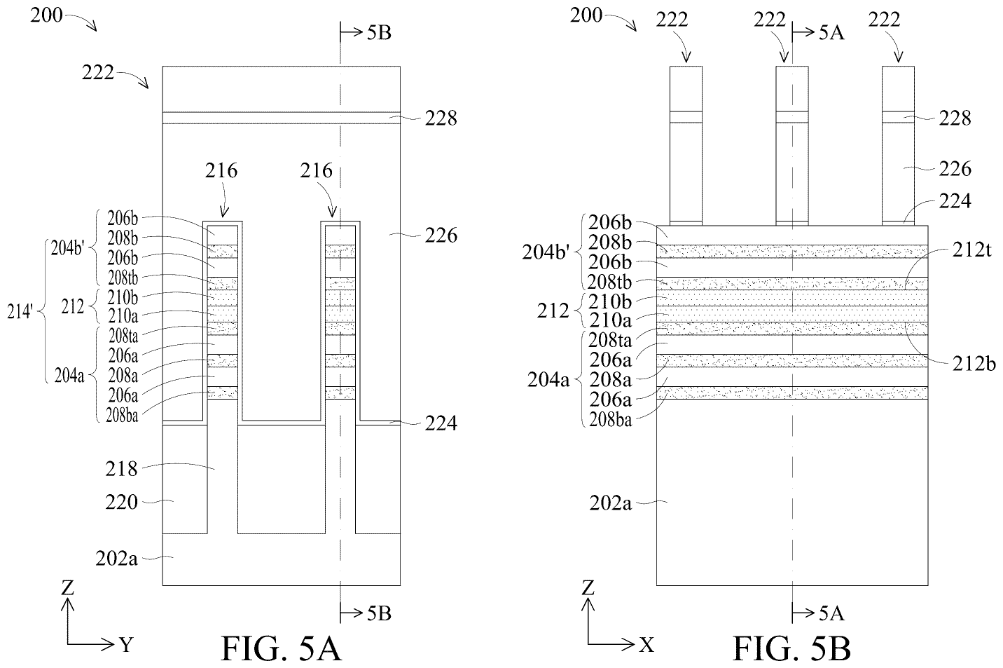

In operation 110, an isolation region 220 and sacrificial gate structures 222 are formed over the fin structures 216, as shown in FIGS. 5A-5B. FIGS. 5A-5B are sectional views of the semiconductor device 200 after operation 110. FIG. 5A is a schematic sectional view along the line 5A-5A in FIG. 5B. FIG. 5B is a schematic sectional view along the line 5B-5B in FIG. 5A. An insulating material may be deposited over the substrate 202a and fill trenches between the fin structures 216. The insulating material may be made of an oxygen-containing material, such as silicon oxide or fluorine-doped silicate glass (FSG); a nitrogen-containing material, such as silicon nitride, silicon oxynitride (SiON), SiOCN, SiCN; a low-k dielectric material; or any suitable dielectric material. The insulating material may be formed by any suitable method, such as low-pressure chemical vapor deposition (LPCVD), plasma enhanced CVD (PECVD) or flowable CVD (FCVD).

A planarization operation, such as a chemical mechanical polishing (CMP) process and/or an etch-back process, is performed such that the tops of the fin structures 216 are exposed from the insulating material. The insulating material may be recessed by removing a portion of the insulating material located between adjacent fin structures 216 to form the isolation region 220, which may be the shallow trench isolation (STI).

The sacrificial gate structures 222 are formed over a portion of the fin structures 216. Each sacrificial gate structure 222 may include a sacrificial gate dielectric layer 224, a sacrificial gate electrode layer 226, and a mask layer 228. The sacrificial gate dielectric layer 224, the sacrificial gate electrode layer 226, and the mask layer 228 may be formed by sequentially depositing blanket layers of the sacrificial gate dielectric layer 224, the sacrificial gate electrode layer 226, and the mask layer 228, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof.

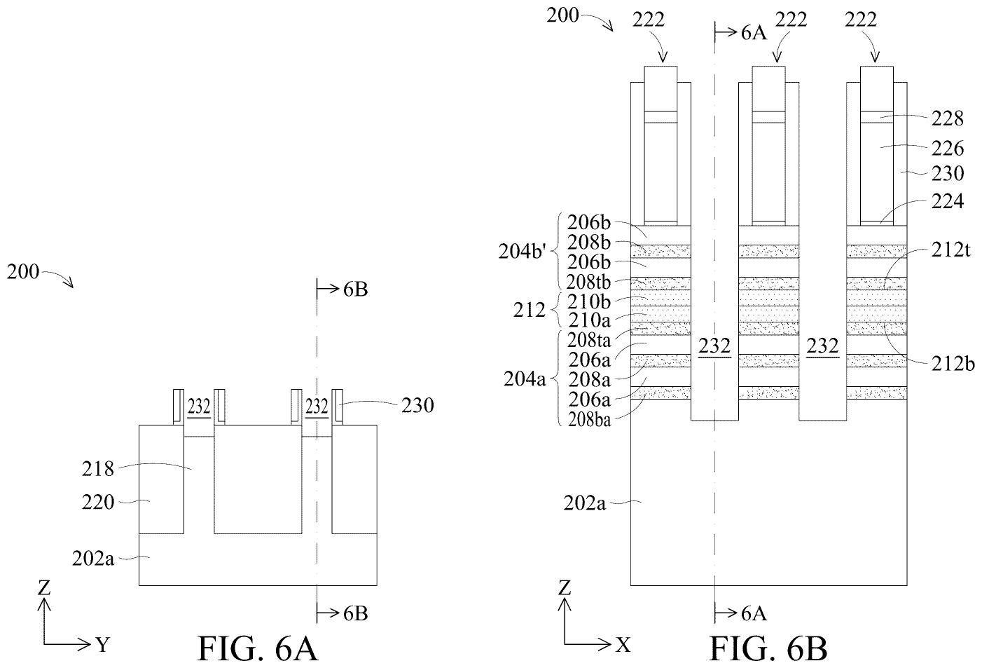

In operation 112, sidewall spacers 230 are formed on sidewalls of the sacrificial gate structures 222, as shown in FIGS. 6A-6B. FIGS. 6A-6B are sectional views of the semiconductor device 200. FIG. 6A is a schematic sectional view along the line 6A-6A in FIG. 6B. FIG. 6B is a schematic sectional view along the line 6B-6B in FIG. 6A. The sidewall spacers 230 may be formed by first depositing a conformal layer that is subsequently etched back to form the sidewall spacers 230. For example, a spacer material layer can be disposed conformally on the exposed surfaces of the semiconductor device 200. The conformal spacer material layer may be formed by an ALD process. Subsequently, anisotropic etch is performed on the spacer material layer using, for example, RIE. During the anisotropic etch process, most of the spacer material layer is removed from horizontal surfaces, such as the tops of the fin structures 216, leaving the sidewall spacers 230 on the vertical surfaces, such as the sidewalls of sacrificial gate structures 222. The sidewall spacers 230 may be made of a dielectric material such as silicon oxide, silicon nitride, silicon carbide, silicon oxynitride, SiCN, silicon oxycarbide, SiOCN, and/or combinations thereof.

By patterning the sacrificial gate structure 222, the complementary channel stack 214 of the fin structures 216 are partially exposed on opposite sides of the sacrificial gate structure 222 and the sidewall spacers 230. The portions of the fin structures 216 that are covered by the sacrificial gate structure 222 and the sidewall spacers 230 serve as channel regions for the semiconductor device 200.

In operation 114, the fin structures 216 that are partially exposed on opposite sides of the sacrificial gate structure 222 and the sidewall spacers 230 are recessed to form source/drain recesses 232, as shown in FIGS. 6A-6B. The exposed portions of the fin structures 216 are selectively recessed by using one or more suitable etch processes, such as dry etch, wet etch, or a combination thereof. In some embodiments, exposed portions of the complementary channel stack 214 of the fin structures 216 are removed, exposing portions of the well portions 218. As shown in FIG. 6A, the exposed portions of the fin structures 216 are recessed to a level at or below a top surface of the isolation region 220. The recess processes may include an etch process that recesses the exposed portions of the fin structures 216.

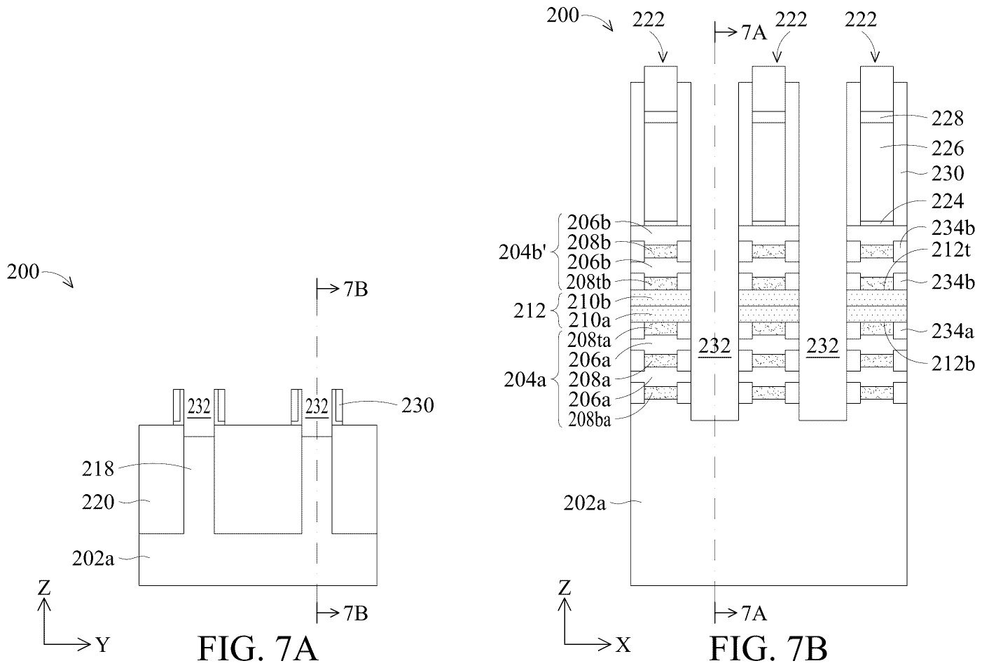

In operation 116, inner spacers 234 are formed as shown in FIGS. 7A-7B. FIGS. 7A-7B are sectional views of the semiconductor device 200 after operation 116. FIG. 7A is a schematic sectional view along the line 7A-7A in FIG. 7B. FIG. 7B is a schematic sectional view along the line 7B-7B in FIG. 7A. Edge portions of the second semiconductor layers 208a and the fourth semiconductor layers 208b of the channel stack 214 are removed horizontally along the X direction. The removal of the edge portions of the second semiconductor layers 208a and the fourth semiconductor layers 208b form cavities in the fin structures 216 under the sidewall spacers 230. In some embodiments, the portions of the second semiconductor layers 208a and the fourth semiconductor layers 208b are removed by a selective wet etching process. In some embodiments, a wet etchant such as, but not limited to, ammonium hydroxide (NH₄OH), tetramethylammonium hydroxide (TMAH), ethylenediamine pyrocatechol (EDP), or potassium hydroxide (KOH) solutions, may be used to remove portions of the second semiconductor layers 208a and the fourth semiconductor layers 208b. Alternatively, a dry etch process may be used. In some embodiments, the dry etch uses chlorine and/or fluorine based chemicals may be used to remove the edge portions of the fourth semiconductor layers 208b. During the etch processing, the second semiconductor layers 208a and the fourth semiconductor layers 208b have a high etch selectivity over the dielectric material in the bonding structure 212.

After removing edge portions of the portions of the second semiconductor layers 208a and the fourth semiconductor layers 208b, a dielectric layer is filled in the cavities to form the inner spacers 234. The inner spacers 234 may be made of a low-K dielectric material, such as SiON, SiCN, SiOC, SiOCN, or SiN. The inner spacers 234 may be formed by first forming a conformal dielectric layer using a conformal deposition process, such as ALD, followed by an etching to remove portions of the conformal dielectric layer other than the inner spacers 234. The etch process may be mainly an isotropic etch or a combination of isotropic etch and anisotropic etch to remove the dielectric layer deposited on sidewall and bottom respectively.

Inner spacers 234b are formed on ends of the topmost fourth semiconductor layer 208tb. Inner spacers 234a are formed on ends of the topmost second semiconductor layer 208ta. The inner spacers 234b, 234a are in contact with the bonding structure 210 at the top surface 212t and the bottom surface 212b respectively.

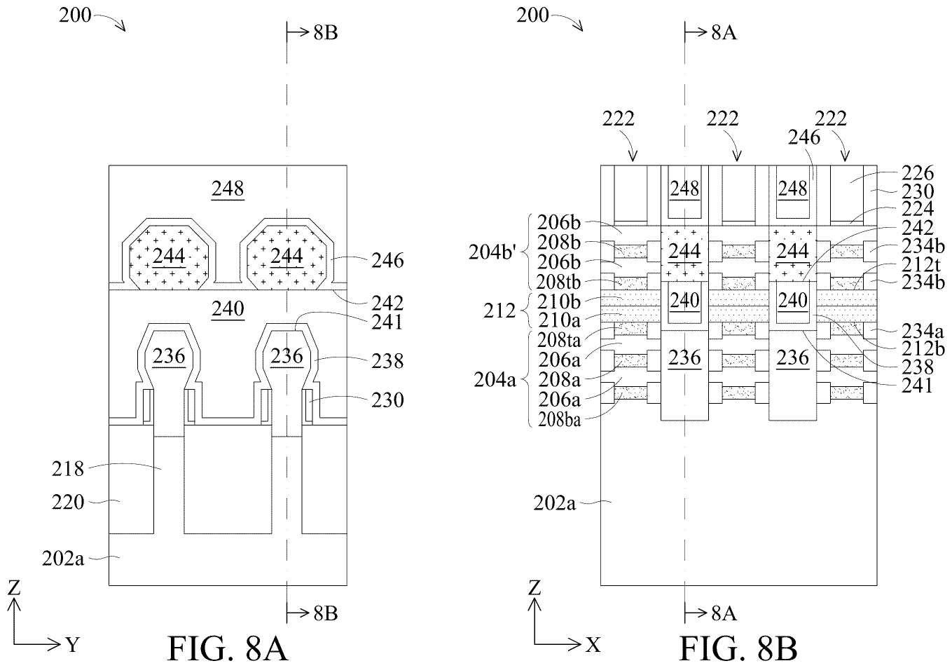

In operation 118, first source/drain regions 236 and second source/drain regions 244 are formed in the source/drain recesses 232 as shown in FIGS. 8A-8B. FIGS. 8A-8B are sectional views of the semiconductor device 200 after operation 118. FIG. 8A is a schematic sectional view along the line 8A-8A in FIG. 8B. FIG. 8B is a schematic sectional view along the line 8B-8B in FIG. 8A. The first source/drain regions 236 are epitaxial features grown from exposed semiconductor surfaces of the well portion 218 of the fin structures 216 and the first semiconductor layers 206a.

The first source/drain regions 236 may include one or more layers of Si, SiP, SiC and SiCP for an n-channel FET or Si, SiGe, Ge for a p-channel FET. In some embodiments, the first source/drain regions 236 includes one or more layers of Si, SiP, SiC and SiCP for a n-channel FET. The first source/drain regions 236 may be formed from the first semiconductor layers 206a. The first source/drain regions 236 may grow both vertically and horizontally to form facets, which may correspond to crystalline planes of the material used for the first semiconductor layers 206a. The first source/drain regions 236 may be formed by an epitaxial growth method using CVD, ALD or MBE.

The source/drain regions 236 are formed in lower portions of the source/drain recesses 232. An upper surface 241 of the source/drain regions 236 lands above the topmost first semiconductor layer 206a. In some embodiments, the upper surface 241 lands within the inner spacers 234a. The dielectric bonding structure 212 disposed between the first channel stack 204a and the second channel stack 204b increases the landing window of the source/drain regions 236, for example, the upper surface 241 may land above the topmost first semiconductor layer 206a and below the top surface 212t of the bonding structure 212 without causing leaks to between the first source/drain regions 236 and the FET to be formed above the bonding structure 212.

A first contact etch stop layer (CESL) 238 and a first interlayer dielectric (ILD) layer 240 are formed over the first source/drain regions 236. The first CESL 238 may be conformally formed on the exposed surfaces of the semiconductor device 200. The first CESL 238 covers the first source/drain regions 236, the sidewall spacers 230, the isolation region 220, and the exposed surface of the channel stack 204. The first CESL 238 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, the first ILD layer 240 is formed on the first CESL 238 over the semiconductor device 200. The materials for the first ILD layer 240 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials comprising Si, O, C, and/or H. The first ILD layer 240 may be deposited by a PECVD process or other suitable deposition technique. In some embodiments, after formation of the first ILD layer 240, the semiconductor device 200 may be subject to a thermal process to anneal the first ILD layer 240.

In some embodiments, an etch back process may be performed so that a top surface 242 of the first CESL 238 and the first ILD layer 240 below the topmost third semiconductor layers 206b so that the third semiconductor layers 206b are exposed to the source/drain recesses 232. In some embodiments, the top surface 242 lands within the inner spacers 234b. The dielectric bonding structure 212 disposed between the first channel stack 204a and the second channel stack 204b increases the landing window of the top surface 242, for example, the top surface 242 may land above the bottom surface 212b of the bonding structure 212 and below the third semiconductor layer 206b without causing leaks to between the FETs to be formed above and below the bonding structure 212.

The second source/drain regions 244 are formed in the source/drain recesses 232. The second source/drain regions 244 are epitaxial features grown from exposed semiconductor surfaces of the third semiconductor layers 206b. The second source/drain regions 244 may include one or more layers of Si, SiGe, Ge for a p-channel FET or Si, SiP, SiC and SiCP for an n-channel FET. In some embodiments, the second source/drain regions 244 includes one or more layers of Si, SiGe, Ge for a p-channel FET. The second source/drain regions 244 may be grow from the third semiconductor layers 206b. The second source/drain regions 244 may grow both vertically and horizontally to form facets, which may correspond to crystalline planes of the material used for the third semiconductor layers 206b. The second source/drain regions 244 may be formed by an epitaxial growth method using CVD, ALD or MBE.

A second CESL 246 and a second ILD layer 248 are formed over the second source/drain regions 244. The second CESL 246 may be conformally formed on the exposed surfaces of the semiconductor device 200. The second CESL 246 covers the second source/drain regions 244, the sidewall spacers 230, and the first ILD layer 240. The second CESL 246 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, the second ILD layer 248 is formed on the second CESL 246 over the semiconductor device 200. The materials for the second ILD layer 248 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials comprising Si, O, C, and/or H. The second ILD layer 248 may be deposited by a PECVD process or other suitable deposition technique. In some embodiments, after formation of the second ILD layer 248, the semiconductor device 200 may be subject to a thermal process to anneal the second ILD layer 248.

After the second ILD layer 248 is formed, a planarization operation, such as CMP, is performed on the semiconductor device 200 to remove portions of the second ILD layer 248, the second CESL 246 and the sacrificial gate electrode layer 226 is exposed.

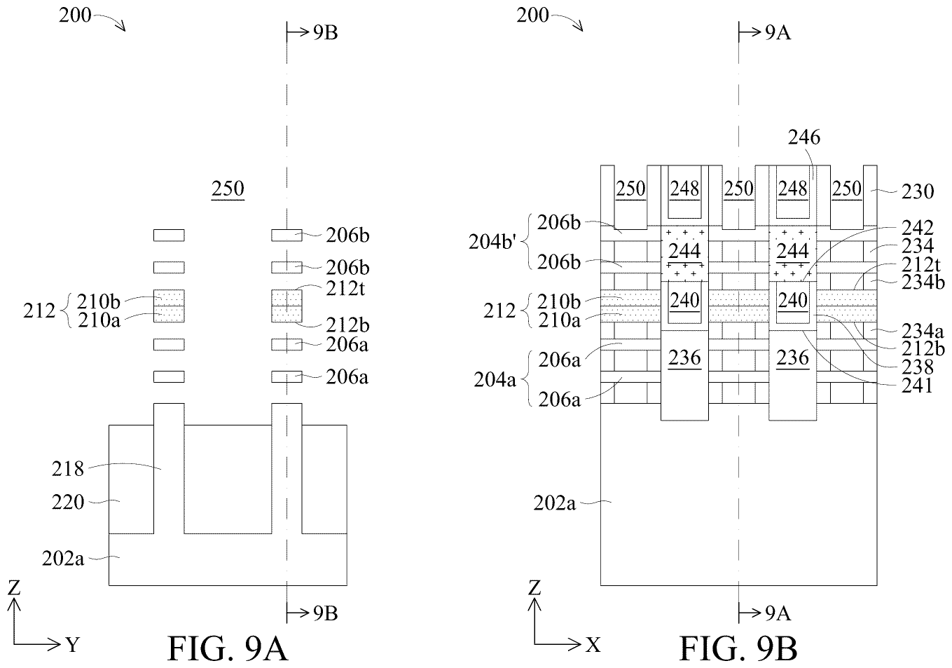

In operation 120, the sacrificial gate structures 222 and the semiconductor layers 208a, 208b are removed, as shown in FIGS. 9A-9A. FIGS. 9A-9A are sectional views of the semiconductor device 200 after operation 120. FIG. 9A is a schematic sectional view along the line 9A-9A in FIG. 9A. FIG. 9A is a schematic sectional view along the line 9A-9A in FIG. 9A. The removal of the sacrificial gate structure 222 forms gate recesses 250 between the sidewall spacers 230 and exposes the portions of the complementary channel stack 214 below the sacrificial gate structure 223. The sacrificial semiconductor layers 208a, 208b may then be selectively removed to expose the first and third semiconductor layers 206a, 206b.

The second ILD layer 248 and the second CESL 246 protect the second source/drain regions 244 and the first source/drain regions 236 during the removal of the sacrificial gate structure 222. The sacrificial gate structure 222 can be removed using plasma dry etching and/or wet etching. The sacrificial gate electrode layer 226 may be first removed by any suitable process, such as dry etch, wet etch, or a combination thereof, followed by the removal of the sacrificial gate dielectric layer 224, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 226 but not the sidewall spacers 230, the inner spacers 234, the bonding structures 212, and the second ILD layer 248, the second CESL 246, and the isolation region 220.

The second and fourth semiconductor layers 208a, 208b are then selectively removed through the gate recesses 250. The removal of the semiconductor layers 208a, 208b exposes the inner spacers 234, the semiconductor layers 206a, 206b, and the bonding structure 212 to the gate recesses 250. The removal process may be any suitable etch processes, such as dry etch, wet etch, or a combination thereof. The etch process may be a selective etch process that removes the semiconductor layers 208a, 208b but not the sidewall spacers 230, the second CESL 246, the second ILD layer 248, the inner spacers 234, the bonding structure 212, the isolation region 220, and the first semiconductor layers 206.

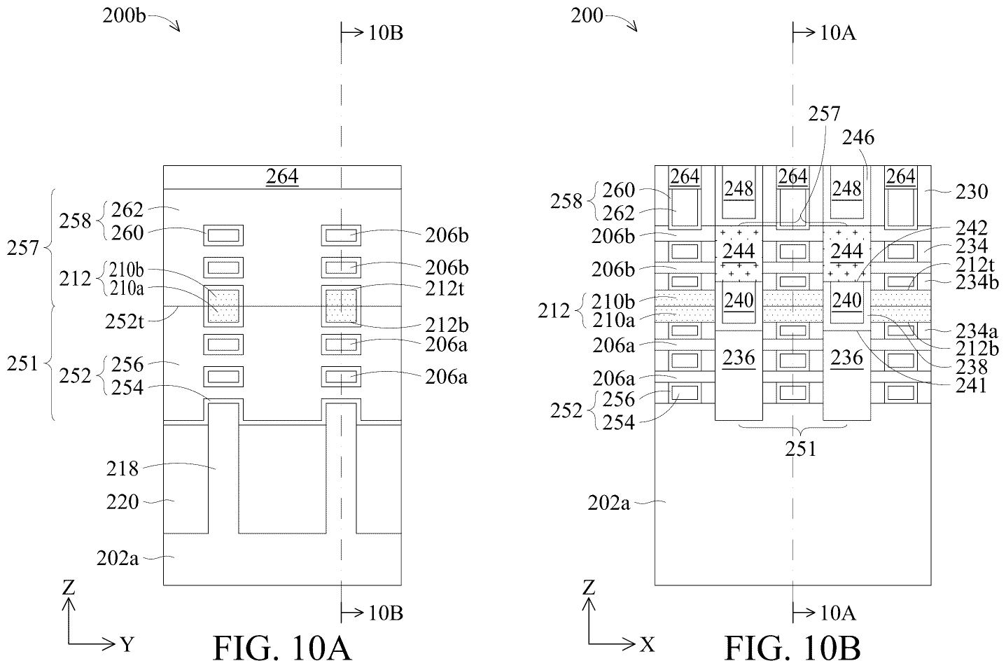

In operation 122, first replacement gate structures 252 and second replacement gate structures 258 are formed around the first semiconductor layers 206a and second semiconductor layers 206b respectively, as shown in FIGS. 10A-10B. FIGS. 10A-10B are sectional views of the semiconductor device 200 after operation 122. FIG. 10A is a schematic sectional view along the line 10A-10A in FIG. 10B. FIG. 10B is a schematic sectional view along the line 10B-10B in FIG. 10A.

The first replacement gate structures 252 include a first gate dielectric layer 254 formed around the first semiconductor layers 206a, and a first gate electrode layer 256 deposited over the first gate dielectric layer 254. The first replacement gate structures 252, the first semiconductor layers 206a, and the first source/drain regions 236 form first transistors 251. The first semiconductor layers 206a connect between the first source/drain regions 236 and function as nanosheet channels of the first transistors 251.

The second replacement gate structures 258 are formed around the third semiconductor layers 206b. The second replacement gate structures 258 include a second gate dielectric layer 260 formed around the third semiconductor layers 206b, and a second gate electrode layer 262 deposited over the second gate dielectric layer 260. The second replacement gate structures 258, the third semiconductor layers 206b, and the second source/drain regions 244 form second transistors 257. The third semiconductor layers 206b connect between the second source/drain regions 244 and function as nanosheet channels of the second transistors 257.

In some embodiments, the first gate dielectric layer 254 and the second gate dielectric layer 260 are formed at the same time. The first gate dielectric layer 254 is deposited on the exposed surfaces of the first semiconductor layers 206a. The second gate dielectric layer 260 is deposited on the exposed surfaces of the third semiconductor layers 206b. The first gate dielectric layer 254 and the second gate dielectric layer 260 may include the same material as the sacrificial gate dielectric layer 224. In some embodiments, the first gate dielectric layer 254 and the second gate dielectric layer 260 may include a high-k dielectric material. In some embodiments, the first gate dielectric layer 254 and the second gate dielectric layer 260 may be formed by conformal processes. In some embodiments, an oxygen-containing layer or an interfacial layer (not shown) may form between the first gate dielectric layer 254 and the first semiconductor layers 206a and between the second gate dielectric layer 260 and the second semiconductor layers 206b respectively. The oxygen-containing layer, the first gate dielectric layer 254 and the second gate dielectric layer 260 may be formed by any suitable processes, such as ALD processes.

The first gate electrode layer 256 is then formed in the gate recesses 250 and on the first gate dielectric layer 254. The first gate electrode layer 256 is formed on the first gate dielectric layer 254 to surround the third semiconductor layer 206b. The first gate electrode layer 256 includes one or more layers of conductive material, such as polysilicon, aluminum, copper, titanium, tantalum, tungsten, cobalt, molybdenum, tantalum nitride, nickel silicide, cobalt silicide, TIN, WN, WCN, TiAl, TiTaN, TiAlN, TaN, TaCN, TaC, TaSiN, metal alloys, other suitable materials, and/or combinations thereof. The first gate electrode layer 256 may be formed by PVD, CVD, ALD, electro-plating, or other suitable method. In some embodiments, the first gate electrode layer 256 includes an n-type gate electrode layer such as TiAlC, TaAlC, TiSiAlC, TiC, TaSiAlC, or other suitable material, and the first gate electrode layer 256 is a gate electrode layer of an NFET.

In some embodiments, an etch back process is performed after deposition of the first electrode layer 254 such that the first replacement gate structure 252 remains at a lower portion of the gate recesses 250. In some embodiments, a planarization process, such as a CMP process, may be performed before the etch back process. In some embodiments, a top surface 252t of the replacement gate structure 252 is in contact with the bonding structure 212, i.e., the top surface 252t lands between the top surface 212t and the bottom surface 212b of the bonding structure 212. The bonding structure 212 prevents leakages between the first replacement gate structure 252 and the second source/drain regions 244.

The second gate electrode layer 262 is formed in the gate recesses 250 and on the second gate dielectric layer 260. The second gate electrode layer 262 is formed on the second gate dielectric layer 260 to surround the third semiconductor layer 206b. The second gate electrode layer 262 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The second gate electrode layer 262 may be formed by PVD, CVD, ALD, electro-plating, or other suitable method. In some embodiments, the second gate electrode layer 262 includes p-type gate electrode layer such as TiN, TaN, TiTaN, TiAlN, WCN, W, Ni, Co, or other suitable material, and the second gate electrode layer 262 is a gate electrode layer of a PFET.

After deposition of the gate electrode layer 262, an etch back process may be performed to etch the second gate electrode layer 262 and the second gate dielectric layer 260 below the sidewall spacers 230. A self-aligned contact etch layer 264 is deposited over the gate electrode layer 262 for subsequent formation of contact features.

The first and second transistors 251, 257 may have different threshold voltages and the control voltage may be applied to the gate electrode layers 256, 262 together.

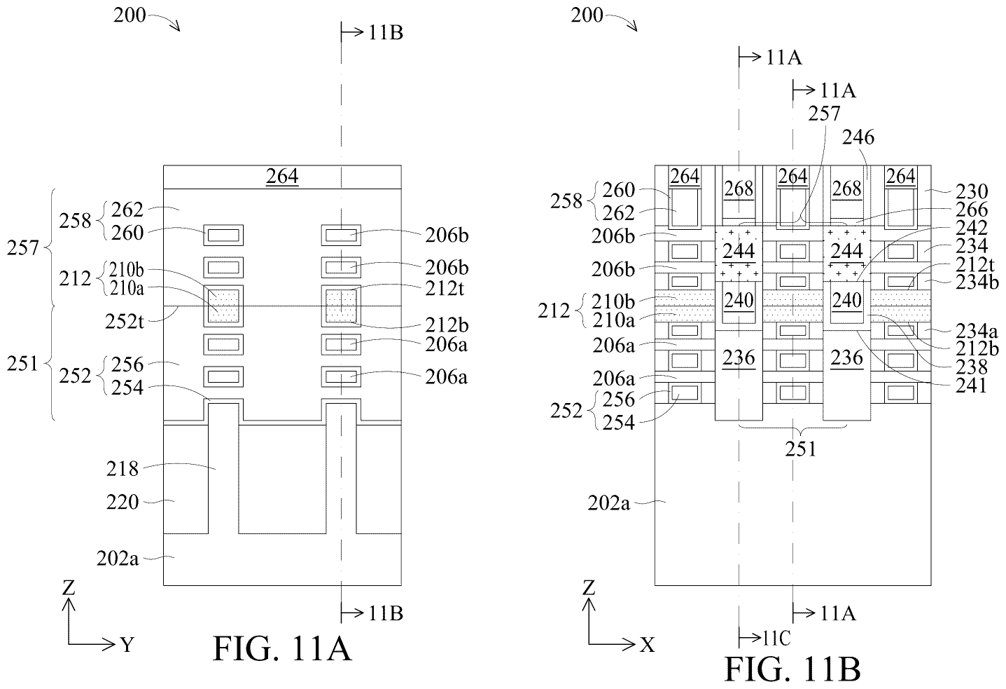

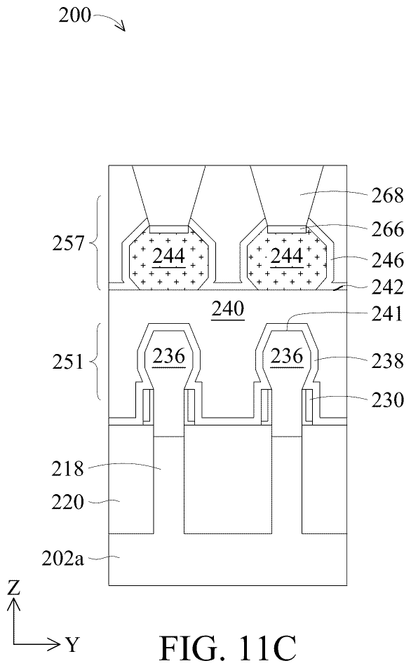

In operation 124, contact features 268 are formed, as shown in FIGS. 11A-11C. FIGS. 11A-11C are sectional views of the semiconductor device 200 after operation 124. FIG. 11A is a schematic sectional view along the line 11A-11A in FIG. 11B. FIG. 11B is a schematic sectional view along the line 11B-11B in FIG. 16A. FIG. 11C is a schematic sectional view along the line 11C-11C in FIG. 11B.

As shown in FIGS. 11A-11C, source/drain contact features 268 and gate contact features (not shown) may be formed to connect with the source/drain regions 244 and the gate electrode layer 262 respectively. In some embodiments, a silicide layer 266 may be formed between the source/drain contact features 268 and the source/drain regions 244. The contact features 268 may be formed from conductive material may including one or more of Ru, Mo, Co, Ni. W, Ti, Ta, Cu, Al, TIN and TaN.

It is understood that the semiconductor device 200 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device 200 may also include backside contacts (not shown) on the backside of the substrate 202a by flipping over the semiconductor device 200, removing the substrate 202a, and selectively connecting source or drain feature/terminal of the first source/drain regions 236 and the gate electrode layer 256.

The bonding layer over the first and second channel stacks may include various composition. For example, the bonding layer may include two or more layers of bonding dielectrics to improve bonding strength and/or device reliability.

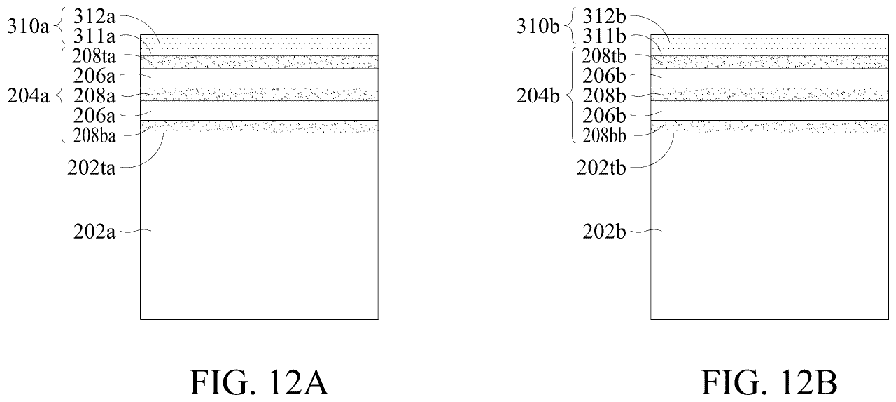

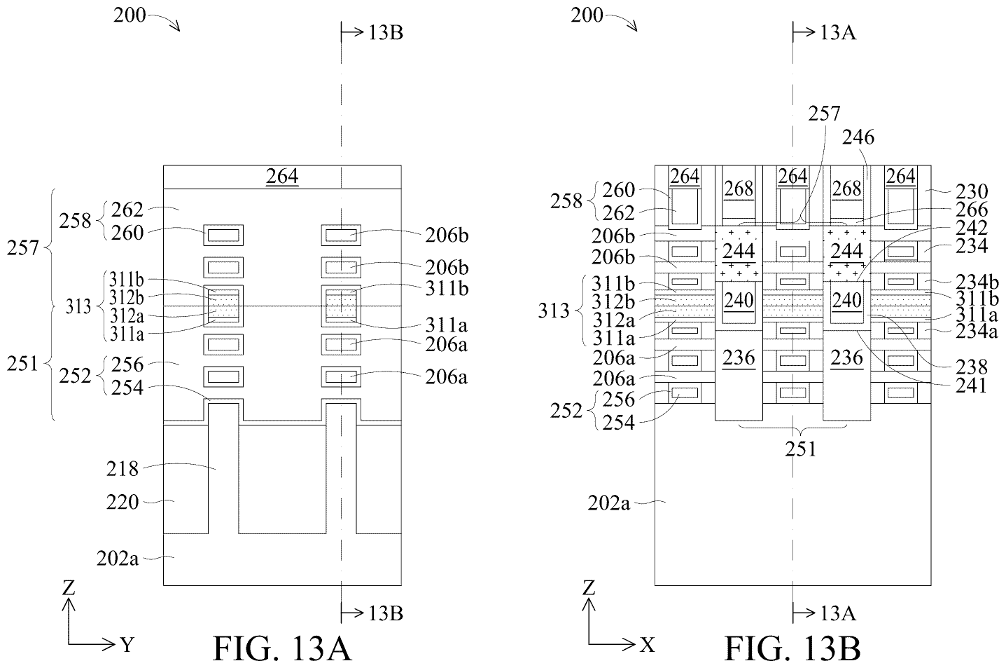

FIGS. 12A-12B and 13A-13B schematically illustrate a semiconductor device 300 according to embodiments of the present disclosure. The semiconductor device 300 is similar to the semiconductor device 200 except that the semiconductor device 300 are formed by bonding two substrates with composite bonding layers, as shown in FIGS. 12A-12B.

In FIGS. 12A and 12B, the first channel stack 204a for bottom devices of the semiconductor device 300 is formed over the first substrate 202a and the second channel stack 204b for top devices of the semiconductor device 300 is deposited on the second substrate 202b. A multilayer bonding dielectric 310a, 310b is deposited over the channel stack 204a, 204b respectively. Each of the multilayer bonding dielectric 310a, 310b may include two or more dielectric layers. In some embodiments, the multilayer bonding dielectric 310a may include a first bonding layer 311a and a top bonding layer 312a.

The first bonding layer 311a is directly deposited over the topmost second semiconductor layer 208ta of the first channel stack 204a. In some embodiments, the first bonding layer 311a may be selected from a dielectric material having a high etch selectivity relative to the second semiconductor layers 208a, so that during subsequent removal of the second semiconductor layers 208a, the first bonding layer 311a may function as an etch stop layer. In some embodiments, the first bonding layer 311a may be selected from silicon carbon-nitride (SiCN), silicon oxy-carbon-nitride (SiOCN), silicon oxide, silicon nitride, a high-k material, or the like.

The top bonding layer 312a is the topmost layer of the multilayer bonding dielectric 310a. The top bonding layer 312a may be selected from a dielectric material suitable for surface treatments related to the bonding process. In some embodiments, the top bonding layer 312a is directly deposited over the first bonding layer 311a. In some embodiments, the top bonding layer 312a may be selected from silicon oxide, silicon nitride, silicon carbon-nitride (SiCN), silicon oxy-carbon-nitride (SiOCN), a high-k material, or the like.

In other embodiments, one or more intermediate dielectric layers may be disposed between the first bonding layer 311a and the top bonding layer 312a. For example, an intermediate dielectric layer may be deposited between the first bonding layer 311a and the top bonding layer 312a to improve adhesion therebetween.

In some embodiments, the multilayer bonding layer 310b include the same composition as the multilayer bonding layer 310a. The multiple bonding layer 310b includes a first bonding layer 311b and a top bonding layer 312b. The multilayer bonding layers 310a, 310b form a symmetrical bonding structure 313 in the semiconductor device 300, as shown in FIGS. 13A-13B. The bonding structure 313 includes the first bonding layers 311a, 311b as outer layers facing the transistors 251, 257, and the top bonding layers 312a, 312b joined together as inner layers. The bonding structure 312 may have a thickness T1 in a range between about 5 nm and about 30 nm.

In some embodiments, the bonding structure 313 may include one or more intermediate dielectric layers between the first bonding layer 311a and the top bonding layer 312a, or between the first bonding layer 311b and the top bonding layer 312b. In other embodiments, the multilayer bonding layer 310b may have different composition as the multilayer bonding layer 310a, and the resulting bonding structure 313 may be asymmetrical.

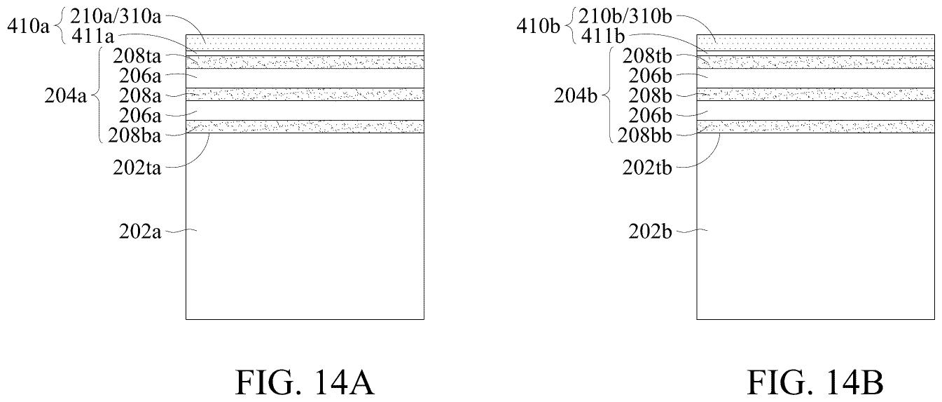

FIGS. 14A-14B, and 15-18 schematically illustrate a semiconductor device 400 according to another embodiment of the present disclosure. The semiconductor device 400 is similar to the semiconductor device 200 except that the semiconductor device 400 are formed using a sacrificial semiconductor layer adjacent a bonding layer, as shown in FIGS. 14A-14B.

In FIGS. 14A and 14B, the first channel stack 204a for bottom devices of the semiconductor device 400 is formed over the first substrate 202a and the second channel stack 204b for top devices of the semiconductor device 400 is deposited on the second substrate 202b.

A sacrificial semiconductor layer 411a is first deposited over the channel stack 204a. A bonding layer 210a or 310a is then deposited over the sacrificial semiconductor layer 411a. The sacrificial semiconductor layer 411a may function as an etch stop layer to protect the bonding layer 210a/310a during subsequent processing.

The sacrificial semiconductor layer 411a may include a semiconductor material having etch selectivity with the semiconductor layers in the channel stacks 204a, 204b. For example, the sacrificial semiconductor layer 411 may include a semiconductor material having etch selectivity with the second semiconductor layers 208a and the fourth semiconductor layers 208b. In some embodiments, the sacrificial semiconductor layer 411a may be formed from the same material as the first semiconductor layers 206a. In some embodiments, the sacrificial semiconductor layer 411a includes epitaxially formed silicon. In other embodiments, the sacrificial semiconductor layer 411a may include SiGe. For example, the sacrificial semiconductor layer 411a, the second semiconductor layers 208a, the fourth semiconductor layers 208b all include SiGe, while the sacrificial semiconductor layer 411a has a different, such as a higher, Ge concentration than the second semiconductor layers 208a and the fourth semiconductor layers 208b. The sacrificial semiconductor layer 411a may have a thickness in a range between about ranging from about 1 nm to about 2 nm.

Similarly, a sacrificial semiconductor layer 411b is first deposited over the channel stack 204b. A bonding layer 210b or 310b is then deposited over the sacrificial semiconductor layer 411b. The sacrificial semiconductor layer 411b may function as an etch stop layer to protect the bonding layer 210b/310b during subsequent processing.

The sacrificial semiconductor layer 411b may include a semiconductor material having etch selectivity with the fourth semiconductor layers 208b. In some embodiments, the sacrificial semiconductor layer 411a may be formed from the same material as the third semiconductor layers 206b. In some embodiments, the sacrificial semiconductor layer 411b includes epitaxially formed silicon or SiGe. The sacrificial semiconductor layer 411b may have a thickness in a range between about ranging from about 1 nm to about 2 nm.

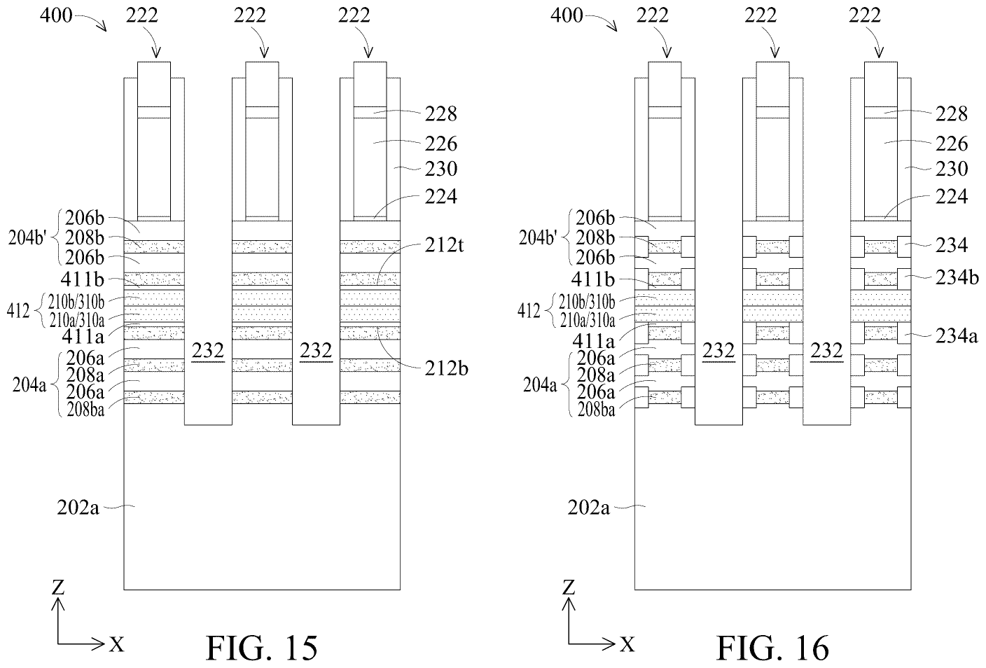

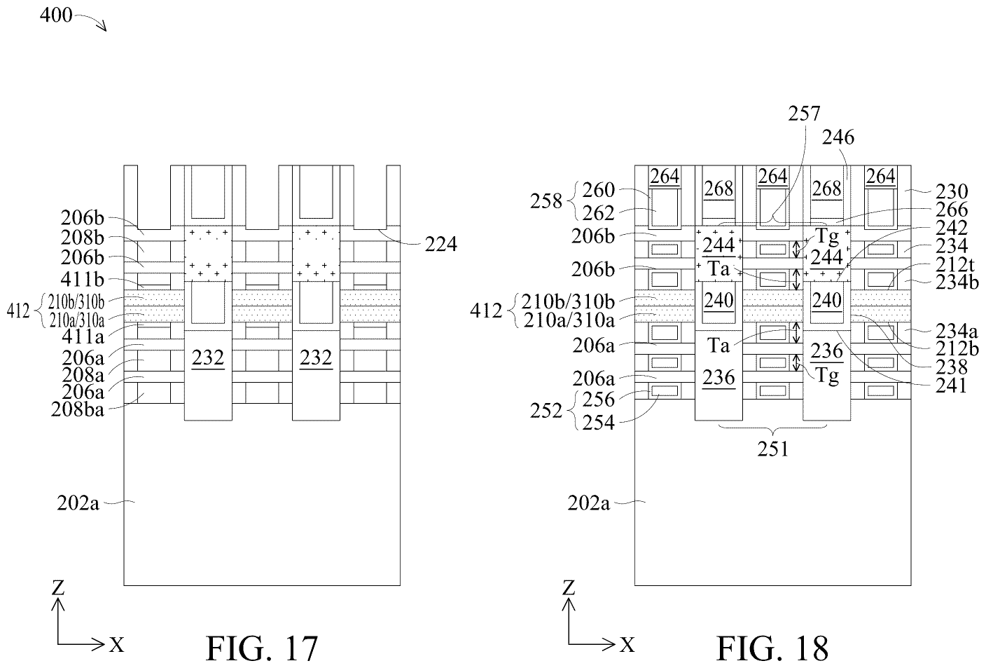

FIGS. 15-18 are schematic sectional views of the semiconductor devices 400 after operations 112, 116, 126, and 132 respectively. As shown in FIG. 15, a bonding structure 412 is formed with the bonding layers 210a/310a and 210b/310b. The bonding structure 412 is sandwiched between the sacrificial semiconductor layers 411a, 411b. As shown in FIG. 16, portions of the sacrificial semiconductor layer 411a, 411b are removed when forming inner spacers 234. As a result, the inner spacers 234a, 234b immediately adjacent the bonding structure 412 may have a greater thickness along the z-axis compared to other inner spacers 234. As shown in FIG. 17, the sacrificial semiconductor layers 411a, 411b protects the bonding structure 412 by functioning as an etch stop during removal of the semiconductor layers 208a, 208b in operation 126. After operation 126, an additional etch processing may be removed prior to formation of the replacement gate structures. In some embodiments, a distance Ta between the topmost semiconductor layer 206a, 206b is greater than the distances Tg between neighboring semiconductor layers 206a, 206b in the semiconductor device 400, as shown in FIG. 18.

Various embodiments or examples described herein offer multiple advantages over the state-of-art technology. For example, the isolation between channels of NFET and PFET is formed from dielectric bonding, therefore, avoiding potential leakage paths to the source/drain regions through the isolation. By using the bonding structure as isolation, it is possible to avoid using SiGe layer with high concentration Ge, thus, avoiding defects caused by the SiGe layer with high Ge concentration. Additionally, device performance is improved because channel orientations of the top and bottom devices can be chosen independently,

It will be understood that not all advantages have been necessarily discussed herein, no particular advantage is required for all embodiments or examples, and other embodiments or examples may offer different advantages.

Some embodiments of the present provide a method comprising forming a first semiconductor stack on a first substrate; forming a second semiconductor stack on a second substrate; bonding the second substrate to the first substrate so that the second semiconductor stack is stacked over the first semiconductor stack; removing the second substrate; and patterning the first semiconductor stack and the second semiconductor stack to form a fin structure; and forming a first transistor and a second transistor from the fin structure, wherein the first transistor comprises first source/drain regions disposed across a portion of the first semiconductor stack, and the second transistor comprises second source/drain regions disposed across a portion of the second semiconductor stack.

Some embodiments of the present disclosure provide a method comprising: forming a fin structure over a first substrate, wherein the fin structure comprises: a first semiconductor channel layer having a first crystalline orientation; a second semiconductor channel layer having a second crystalline orientation; and a bonding structure between the first semiconductor channel layer and second semiconductor channel layer; forming a sacrificial gate structure over the fin structure; etching the fin structure on opposite sides of the fin structure; forming first source/drain regions in contact with the first semiconductor channel layer; depositing a first CESL (contact etch stop layer) over the first source/drain regions; depositing a first ILD (interlayer dielectric) layer on the first CESL; forming second source/drain regions in contact with the second semiconductor channel layer; depositing a second CSEL over the second source/drain regions; and depositing a second ILD layer on the second CESL.

Some embodiments of the present disclosure provide a semiconductor device, comprising: a first channel layer; a first gate dielectric layer surrounding the first channel layer; a first gate electrode layer disposed on the first gate dielectric layer; first source/drain regions in contact with the first channel layer; a second channel layer disposed below and aligned with the first channel layer; a second gate dielectric layer surrounding the second channel layer; a second gate electrode layer disposed on the second gate dielectric layer; second source/drain regions in contact with the second channel layer; and a bonding structure disposed between the first channel layer and the second channel layer and aligned with the first and second channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a first channel stack on a front side of a first substrate;
depositing a bonding layer on the first channel stack;
bonding the first substrate to a second substrate; bonding the first substrate so that a second substrate;
thinning the first substrate from a backside of the first substrate; and
patterning the first channel stack from the backside of the first substrate to form a fin structure;
forming a sacrificial gate structure over the fin structure, wherein the sacrificial gate structure covers a portion of the first channel stack;
recess etching the fin structure;
forming a first transistor from the portion of the first channel stack covered by the sacrificial gate structure, wherein the first transistor comprises first source/drain regions disposed across the portion of the first channel stack.

2. The method of claim 1, wherein depositing the bonding layer comprises:
depositing a first dielectric layer over the first channel stack.

3. The method of claim 1, wherein forming the first channel stack comprises:
alternately depositing two or more first semiconductor layers and two or more second semiconductor layers.

4. The method of claim 3, wherein forming the first channel stack further comprises:
depositing an etch stop layer on the first channel stack, wherein the bonding layer is formed on the etch stop layer

5. The method of claim 4, wherein the etch stop layer comprises a dielectric material.

6. The method of claim 4, wherein the etch stop layer comprises a semiconductor material.

7. The method of claim 1, wherein the first substrate has a first crystalline orientation, and the second substrate has a second crystalline orientation different from the first crystalline orientation.

8. The method of claim 7, further comprising: aligning the first and second substrate according to the first and second crystalline orientations prior to bonding the first substrate to the second substrate.

9. A method, comprising:
forming a fin structure over a first semiconductor substrate having a first crystalline orientation, wherein the fin structure comprises:
two or more first semiconductor channel layers having the first crystalline orientation;
two or more first sacrificial layers alternately stacked with the two or more first semiconductor channel layers;
two or more second semiconductor channel layers having a second crystalline orientation different from the first crystalline orientation; and
two or more second sacrificial layers alternately stacked with the two or more second semiconductor channel layers;
forming a sacrificial gate structure over the fin structure;
etching the fin structure on opposite sides of the fin structure;
forming first source/drain regions in contact with the two or more first semiconductor channel layers;
depositing a first CESL (contact etch stop layer) over the first source/drain regions;
depositing a first ILD (interlayer dielectric) layer on the first CESL;
forming second source/drain regions in contact with the two or more second semiconductor channel layers;
depositing a second CSEL over the second source/drain regions; and
depositing a second ILD layer on the second CESL.

10. The method of claim 9, wherein the fin structure further comprising a bonding structure between the two or more first semiconductor channel layers and the two or more second semiconductor channel layers.

11. The method of claim 10, wherein forming the fin structure comprising:
alternately forming the two or more first semiconductor channel layers and the two or more first sacrificial layers on the first substrate;
depositing a first bonding layer over the two or more first semiconductor channel layers and the two or more first sacrificial layers;
alternately forming the two or more second semiconductor channel layers and the two or more second sacrificial layers on a second substrate having the second crystalline orientation;
depositing a second bonding layer over the two or more second semiconductor channel layers and two or more second sacrificial layers; and
bonding the first and second bonding layers to form the bonding structure.

12. The method of claim 11, further comprising: prior to bonding the first and second bonding layers, aligning the first and second substrates according to the first and second crystalline orientations.

13. The method of claim 11, further comprising depositing an etch stop layer over the two or more first semiconductor channel layers and two or more first sacrificial layers prior to depositing the first bonding layer.

14. The method of claim 13, wherein the etch stop layer comprises a dielectric material.

15. The method of claim 13, wherein the etch stop layer comprises silicon.

16. A semiconductor device, comprising:
a first channel layer having a first crystalline orientation;
a first gate dielectric layer surrounding the first channel layer;
a first gate electrode layer disposed on the first gate dielectric layer;
first source/drain regions in contact with the first channel layer;
a second channel layer disposed below and aligned with the first channel layer, wherein the second channel layer has a second crystalline orientation different from the first crystalline orientation;
a second gate dielectric layer surrounding the second channel layer;
a second gate electrode layer disposed on the second gate dielectric layer; and
second source/drain regions in contact with the second channel layer.

17. The semiconductor device of claim 16, further comprising a bonding structure surrounded by the first gate dielectric layer and the second gate dielectric layer.

18. The semiconductor device of claim 17, wherein the bonding structure comprises:
a first dielectric bonding layer; and
a second dielectric bonding layer bonded to the first dielectric bonding layer by a dielectric-to-dielectric direct bonding.

19. The semiconductor device of claim 17, wherein the bonding structure further comprises:
a third dielectric layer facing the first channel layer; and
a fourth dielectric layer facing the second channel layer.

20. The semiconductor device of claim 16, wherein a top surface of the first channel layer is on a (100) plane and a top surface of the second channel layer is on a (110) plane.
